(19) United States
(12) Patent Application Publication
(10) Pub. No.: US 2012/0229178 A1
(43) Pub. Date: Sep. 13, 2012

(54) Method and apparatus for calibrating frequency

(75) Inventors: Xiangguang Feng, Wuxi City (CN); Qilong Gu, Wuxi City (CN); Qi Yu, Wuxi City (CN)

(73) Assignee: RFdot Microelectronics Inc.

(21) Appl. No.: 13/414,540

(22) Filed: Mar. 7, 2012

(30) Foreign Application Priority Data
Mar. 8, 2011 (CN) 20110054538.7

(51) Int. Cl. H03K 21/00

(52) U.S. Cl. 327/115

(57) ABSTRACT

Methods and apparatuses for calibrating frequency are provided according to the embodiment of the present disclosure. A method for calibrating frequency may comprise: providing an actual frequency of a reference frequency signal and a frequency offset between the actual frequency of the reference frequency signal and the expected frequency of the reference frequency signal; determining a frequency division ratio according to the frequency of a target frequency signal and the expected frequency of the reference frequency signal; determining a calibration value of the frequency division ratio according to the frequency offset; providing a calibrated frequency division ratio by calibrating the frequency division ratio according to the calibration value; and providing the target frequency signal by dividing the frequency of the reference frequency signal according to the calibrated frequency division ratio.

### CROSS-REFERENCE TO RELATED APPLICATIONS

This application claims the benefit of priority to China Patent Application with Application Number, 201110054538.7, filed on Mar. 8, 2011.

### FIELD OF THE INVENTION

At least one embodiment of the present disclosure pertains to clock signals in electronic circuits, and more particularly to a method and an apparatus for calibrating frequency.

### BACKGROUND

In clock chip design, the precision of a clock frequency is determined by the frequency precision of quartz crystal used in the clock. In order to normalize and synchronize operations between electronic devices, it is very important to have a precise clock signal in electronic circuit designs. A clock signal in electronic circuits is usually generated by a crystal oscillator. The crystal oscillator is an electric circuit that generates the clock signal with a fixed frequency according to mechanical resonances of an oscillating crystal, i.e. piezoelectric materials. The fixed frequency may be used for time-measuring, providing clock signals for digital integrated circuits and stabilizing frequencies in wireless emitters and receivers. Temperature is one factor that may influence the operations of a piezoelectric material and a crystal oscillator. When temperature varies, the output frequency of a crystal oscillator fluctuates accordingly. In general, the frequency of quartz crystal has a frequency stability between 20 ppm to 100 ppm. In applications requiring high precisions, i.e. global positioning systems, this frequency precision may not be good enough. In applications that require the clock error of a chip or a device to be less than 5 minutes in a year, the frequency stability must be less than 10 ppm. An ordinary crystal oscillator or divided frequency may not meet this requirement.

Therefore, the present inventors have recognized that there is value and a need to provide methods and systems for calibrating frequency.

### SUMMARY

According to one embodiment of the present disclosure, a method and an apparatus for calibrating frequency disclosed may provide a precise target frequency signal with easy implementation and broad applications. The method may comprise calibrating the frequency division ratio of the division of a reference frequency signal to a target frequency signal, and dividing the frequency of the reference frequency signal according to the frequency division ratio.

According to another embodiment of the present disclosure, a method for calibrating frequency may include: providing an actual frequency of a reference frequency signal and a frequency offset between the actual frequency of the reference frequency signal and the expected frequency of the reference frequency signal; determining a frequency division ratio according to the frequency of a target frequency signal and the expected frequency of the reference frequency signal; determining a calibration value of the frequency division ratio according to the frequency offset; providing a calibrated frequency division ratio by calibrating the frequency division ratio according to the calibration value; and providing the target frequency signal by dividing the frequency of the reference frequency signal according to the calibrated frequency division ratio.

In accordance with another embodiment of the present disclosure, the frequency division ratio may be the ratio between the expected frequency of the reference frequency signal and the frequency of the target frequency signal. The calibration value may include an integral calibration value and a fractional calibration value. The above mentioned step for providing the calibrated frequency division ratio by calibrating the frequency division ratio according to the calibration value may include: providing the integral part of the calibrated frequency division ratio by adding or subtracting the frequency division ratio from the integral calibration value, and taking the fractional calibration value as the residual part of the calibrated frequency division ratio.

In accordance with another embodiment of the present disclosure, the above mentioned step for providing the target frequency signal by dividing the frequency of the reference frequency signal according to the calibrated frequency division ratio may include: providing a counting value by counting the cycles of the reference frequency signal; and starting one cycle of the target frequency signal when the counting value starts from an initial value, and ending the cycle of the target frequency signal when the counting value reaches the integral part of the calibrated frequency division ratio, and re-counting the cycles of the reference frequency signal from the initial value to generate next cycle of the target frequency signal. When one cycle of the target frequency signal is generated, the fractional calibration value may be added to the residual part of the calibrated frequency division ratio, and, after accumulated residues reaches an integer value, a post-carry integral part of the calibrated frequency division ratio may be provided by adding a carry from the integer value to the integral part of the calibrated frequency division ratio, and the fractional calibration value may be continuously added to the new residual part of the calibrated frequency division ratio. After one cycle of the target frequency signal is generated according to the post-carry integral part of the calibrated frequency division ratio, the post-carry integral part of the calibrated frequency division ratio may be reset to the initial integral value.

In accordance with yet another embodiment of the present disclosure, the integral calibration value and the fractional calibration value may be determined according to, respectively, the number of cycles and the residue cycles of the expected frequency within 1/fₜ of the frequency offset, in which fₜ is the frequency of the target frequency signal.

In accordance with yet another embodiment of the present disclosure, the frequency division ratio may be equal to one half of the ratio between the expected frequency of the reference frequency signal and the frequency of the target frequency signal. The calibration value may include an integral calibration value and a fractional calibration value. The step of providing calibrated frequency division ratio by calibrating according to the calibration value may comprise: providing the integral part of the calibrated frequency division ratio by adding or subtracting the integral calibration value to or from the frequency division ratio; and providing the fractional calibration value as the residual part of the calibrated frequency division ratio.

In accordance with yet another embodiment of the present disclosure, the step of providing the target frequency signal by dividing the frequency of the reference frequency signal according to the calibrated frequency division ratio may include: providing a counting value by counting the cycles of the reference frequency signal; and inverting the target frequency signal when the count value reaches the calibrated frequency division ratio, and recounting the cycles of the reference frequency signal by starting from an initial value of the counting value; in which, after a half cycle of the target frequency signal is generated, the fractional calibration value may be added to the residual part of the calibrated frequency division ratio, and, after accumulated residues reach an integer value, a post-carry integer of the calibrated frequency division ratio may be provided by adding a carry from the integer value to the integral part of the calibrated frequency division ratio, and the fractional calibration value may be continuously added to the new residual part of the calibrated frequency division ratio. After one half cycle of target frequency signal is generated according to the post-carry integral part of the calibrated frequency division ratio, the post-carry integral part of the calibrated frequency division ratio may be reset to the initial integral value.

In accordance with yet another embodiment of the present disclosure, the integral calibration value and the fractional calibration value may be determined according to, respectively, the number of double cycles and the residue of double cycles of the expected frequency within ½fₜ of the frequency offset, in which fₜ is the frequency of target frequency signal.

In accordance with yet another embodiment of the present disclosure, an apparatus for calibrating frequency may include: a module for acquiring a temperature of a crystal oscillator and providing the temperature; a module for generating a frequency signal, and providing an actual frequency of a reference frequency signal from the crystal oscillator; a module for generating a frequency offset, providing the frequency offset between the actual frequency of the reference frequency signal and the expected frequency of the reference frequency signal according to the temperature; and a module for calibrating frequency, determining a frequency division ratio according to the frequency of the target frequency signal and the expected frequency of the reference frequency signal, determining a calibration value of the frequency division ratio according to the frequency offset, providing the calibrated frequency division ratio by calibrating the frequency division ratio according to the calibration value, and determining the target frequency signal by dividing the frequency of the reference frequency signal according to the calibrated frequency division ratio.

In accordance with yet another embodiment of the present disclosure, the frequency division ratio may be the ratio between the expected frequency of the reference frequency signal and the frequency of the target frequency signal. The calibration value may consist of an integral calibration value and a fractional calibration value. Providing the calibrated frequency division ratio by calibrating the frequency division ratio according to the calibration value may include: providing the integral part of the calibrated frequency division ratio by adding or subtracting the integral calibration value to or from the frequency division ratio; and providing the fractional calibration value as the residual part of the calibrated frequency division ratio.

In accordance with yet another embodiment of the present disclosure, determining the target frequency signal by dividing the frequency of the reference frequency signal according to the calibrated frequency division ratio may comprise the steps of: providing a counting value by counting the cycles of the reference frequency signal; and starting one cycle of the target frequency signal when the counting value starts from an initial value, and ending the cycle of the target frequency signal when the counting value reaches to the integral part of the calibrated frequency division ratio, and re-counting the cycles of the reference frequency signal from the initial value to generate next cycle of the target frequency signal. When one cycle of the target frequency signal is generated, the fractional calibration value may be added to the residual part of the calibrated frequency division ratio, and, after accumulated residues reaches an integer value, a post-carry integral part of the calibrated frequency division ratio may be provided by adding a carry from the integer value to the integral part of the calibrated frequency division ratio, and the fractional calibration value may be continuously added to the new residual part of the calibrated frequency division ratio. After one cycle of the target frequency signal is provided according to the post-carry integral part of the calibrated frequency division ratio, the post-carry integral part of the calibrated frequency division ratio may be reset to the initial integral part of the calibrated frequency division ratio.

In accordance with yet another embodiment of the present disclosure, the integral calibration value and the fractional calibration value may be determined according to, respectively, the number of cycles and the residue cycles of the expected frequency within 1/fₜ of the frequency offset, in which fₜ is the frequency of the target frequency signal.

In accordance with yet another embodiment of the present disclosure, the frequency division ratio may be equal to one half of the ratio between the expected frequency of the reference frequency signal and the frequency of the target frequency signal. The calibration value may include an integral calibration value and a fractional calibration value. Providing calibrated frequency division ratio by calibrating frequency division ratio according to the calibration value may include: providing the integral part of the calibrated frequency division ratio by adding or subtracting the integral calibration value to or from the frequency division ratio; and providing the fractional calibration value as the residual part of the calibrated frequency division ratio.

In accordance with yet another embodiment of the present disclosure, the step of providing the target frequency signal by dividing the frequency of the reference frequency signal according to the calibrated frequency division ratio may include: providing a counting value by counting the cycles of the reference frequency signal; and inverting the target frequency signal when the count value reaches the calibrated frequency division ratio, and recounting the cycles of the reference frequency signal by starting from an initial value of the counting value; in which, after a half cycle of the target frequency signal is generated, the fractional calibration value may be added to the residual part of the calibrated frequency division ratio, and, after accumulated residues reach an integer value, a post-carry integer of the calibrated frequency division ratio may be provided by adding a carry from the integer value to the integral part of the calibrated frequency division ratio, and the fractional calibration value may be continuously added to the new residual part of the calibrated frequency division ratio. After one half cycle of target frequency signal is generated according to the post-carry integral part of the calibrated frequency division ratio, the post-carry integral part of the calibrated frequency division ratio may be reset to the initial integral value.

In accordance with yet another embodiment of the present disclosure, the integral calibration value and the fractional calibration value may be determined according to, respectively, the number of double cycles and the residue of double cycles of the expected frequency within ½fₜ of the frequency offset, in which fₜ is the frequency of target frequency signal.

In accordance with yet another embodiment of the present disclosure, method and apparatus may be provided to correct a frequency division ratio according to the frequency offset of a reference frequency signal, divide the frequency of the reference frequency signal according to a calibrated frequency division ratio, and provide a precise target frequency signal.

### BRIEF DESCRIPTION OF THE DRAWINGS

One or more embodiments of the present disclosure are illustrated by way of example and not limited in the figures of the accompanying drawings, in which like references indicate similar elements.

FIG. 1 illustrates a flow diagram for calibrating frequency according to one embodiment of the present disclosure.

FIG. 2 illustrates a schematic diagram of frequencies of a crystal oscillator versus temperatures according to another embodiment of the present disclosure.

FIG. 3 illustrates a flow diagram for calibrating frequency according to yet another embodiment of the present disclosure.

### DETAILED DESCRIPTION

The following description and drawings are illustrative and are not to be construed as limiting. Numerous specific details are described to provide a thorough understanding of the disclosure. However, in certain instances, well-known details are not described in order to avoid obscuring the description. References to “one embodiment” or “an embodiment” in the present disclosure can be, but not necessarily are, references to the same embodiment; and, such references mean at least one of the embodiments.

Reference in this specification to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various requirements are described which may be requirements for some embodiments but not other embodiments.

The terms used in this specification generally have their ordinary meanings in the art, within the context of the disclosure, and in the specific context where each term is used. Certain terms that are used to describe the disclosure are discussed below, or elsewhere in the specification, to provide additional guidance to the practitioner regarding the description of the disclosure. For convenience, certain terms may be highlighted, for example using italics and/or quotation marks. The use of highlighting has no influence on the scope and meaning of a term; the scope and meaning of a term is the same, in the same context, whether or not it is highlighted. It will be appreciated that the same thing can be said in more than one way.

Consequently, alternative language and synonyms may be used for any one or more of the terms discussed herein, but should not be placed based upon whether or not a term is elaborated or discussed herein. Synonyms for certain terms are provided. A recital of one or more synonyms does not exclude the use of other synonyms. The use of examples anywhere in this specification, including examples of any term discussed herein, is illustrative only, and is not intended to further limit the scope and meaning of the disclosure or of any exemplified term. Likewise, the disclosure is not limited to various embodiments given in this specification.

Without intent to further limit the scope of the disclosure, examples of instruments, apparatus, methods and their related results according to the embodiments of the present disclosure are given below. Note that titles or subtitles may be used in the examples for convenience of the reader, which in no way should limit the scope of the disclosure. Unless otherwise defined, all technical and scientific terms used herein have the same meaning as commonly understood by one of ordinary skill in the art to which this disclosure pertains. In the case of conflict, the present document, including definitions, will control.

In accordance with one embodiment of the present disclosure, a method for calibrating frequency may include the steps of adjusting a frequency division ratio according to the frequency offset of a reference frequency signal, and providing a required target frequency signal by dividing the frequency of the reference frequency signal according to a calibrated frequency division ratio.

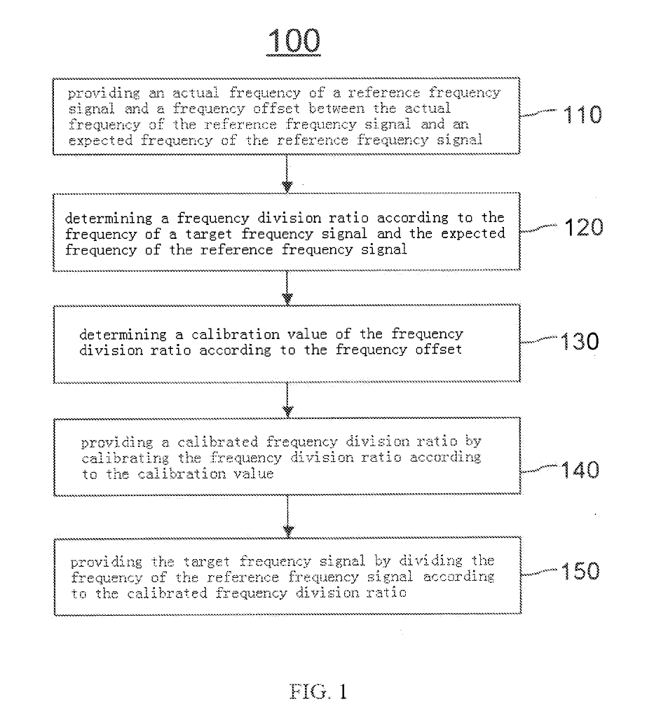

FIG. 1 illustrates a flow diagram for calibrating frequency according to one embodiment of the present disclosure. The flow diagram 100 for calibrating frequency may include the following steps.

At step 110, an actual frequency of a reference frequency signal and a frequency offset between the actual frequency of the reference frequency signal and the expected frequency of the reference frequency signal may be provided.

The reference frequency signal may be generated by a crystal oscillator. Since the output frequency of a crystal oscillator may be affected by its temperature and has a frequency offset, the actual frequency of the reference frequency signal and the expected frequency of the reference frequency signal, which is generated by the crystal oscillator, generally show a frequency offset. For example, the expected frequency or an ideal frequency of the reference frequency signal generated by a crystal oscillator is 32768 Hz. Because of temperature fluctuations, an actual frequency provided may be 32780 Hz or 32800 Hz, which depends on magnitude of the frequency offset.

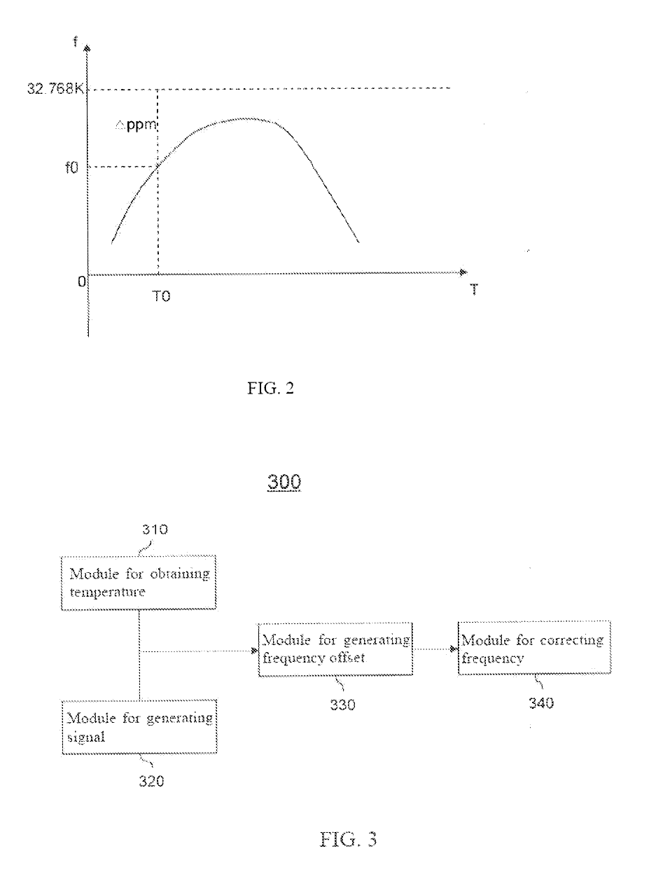

The symbol, Δppm, may be used to identify the frequency offset. The Δppm may be related to the temperature of a crystal oscillator. In general, each manufactured crystal oscillator may have an output frequency depending on the temperature of its internal material, as illustrated in FIG. 2. As shown in FIG. 2, a different temperature may correspond to a different output frequency from the crystal oscillator. The difference between an actual frequency and an expected frequency may be indicated as Δppm. For example, at the temperature, T₀, the actual frequency f₀ is 32.780 kHz, which is different from the expected frequency 32.768 kHz. The offset Δppm is (32768-32780)/32768*10⁶=244.1 ppm.

In some implementations, a lookup table for frequency offsets related to temperature may be provided according to a temperature-frequency characteristic, as illustrated in FIG. 2. The corresponding frequency offset may be provided in accordance with a particular temperature. In some implementations, an algorithm for temperature-related frequency offsets may also be produced according to a temperature-frequency characteristic, in which a frequency offset may be provided in accordance with the corresponding temperature.

In some implementations, the temperature of a crystal oscillator may be sensed by a temperature sensor. A digital temperature may be provided by converting an analog temperature signal. Depending on the temperature-frequency characteristic of each specific crystal oscillator, an actual output frequency of a specific crystal oscillator may be provided. The frequency offset needed for calibration may be provided according to the actual frequency. In some implementations, a corresponding frequency offset may be provided directly according to the digital temperature provided.

At step 120, a frequency division ratio according to the frequency of a target frequency signal and the expected frequency of the reference frequency signal may be determined.

In some implementations, a frequency division ratio may be the ratio between the expected frequency of the reference frequency signal and the frequency of the target frequency signal. If the expected frequency of the reference frequency signal is fₘ, and the frequency of the target frequency signal is fₜ, then the frequency division ratio may be indicated as fₘ/fₜ. For example, if the expected frequency fₘ is 32768 Hz, and the frequency of target frequency signal fₜ is 1 Hz, the frequency division ratio may be equal to 32768 or 2¹⁵. For another example, if the expected frequency fₘ is 32768 Hz, and the target frequency signal fₜ is 2 Hz, then the frequency division ratio is equal to 16384, or 2¹⁴.

In some implementations, the frequency division ratio may also be one half of the ratio between the expected frequency of the reference frequency signal and the frequency of the target frequency signal, which may be indicated as fₘ/2fₜ. For example, if the expected frequency fₘ is 32768 Hz, and the target frequency signal fₜ is 1 Hz, then the frequency division ratio is equal to 16384, or 2¹⁴. For another example, if the expected frequency fₘ is equal to 32768 Hz, and the target frequency signal fₜ is 2 Hz, and then frequency division ratio is equal to 8192 or 2¹³.

At step 130, a calibration value of the frequency division ratio according to the frequency offset may be determined.

The frequency division ratio may be provided according to the expected frequency. In general, there may be a frequency offset between an actual frequency of reference frequency and the expected frequency. A calibration value for the frequency division ratio may be provided according to the frequency offset. The calibration value may include an integral calibration value and a fractional calibration value.

In accordance with yet another embodiment of the present disclosure, two methods for providing calibration value may be provided with respect to two different ways for providing a frequency division ratio.

When a frequency division ratio is the ratio between the expected frequency of the reference frequency signal and the frequency of the target frequency signal, the integral calibration value may be determined according to the number of cycles of the expected frequency within 1/fₜ of the frequency offset, and fractional calibration value may be determined according to the residue after determining the integral cycles of the expected frequency within 1/ft of the frequency offset. In other words, the integral calibration value may be defined as the integral part of the ratio between the frequency offset, Δppm, to the ppm value of the cycles of expected frequency, and the fraction calibration may be defined as the residual part of the ratio between the frequency offset, Δppm, to the ppm value of the cycles of expected frequency.

In some implementations, when the expected frequency of the reference frequency signal is 32768 Hz, the ppm value of one cycle of expected frequency is equal to (1/32768*10⁶)=30.5. Thus, when the frequency offset Δppm is 100 ppm, and the frequency of target frequency signal fₜ is 1 Hz, the frequency offset, Δppm, may occupy 3 cycles of the expected frequency, with a residue part of 8.5. In other words, the integral calibration value is equal to 3, and the fractional calibration value is equal to 8.5. For another example, if the frequency of target frequency signal fₜ is equal to 2 Hz, then one half of the frequency offset Δppm equals 50 ppm, which occupies one cycle of the expected frequency, with a residue part of 19.5. In other words, the integral calibration value is equal to 1, and the fractional calibration value is equal to 19.5. In some other implementations, when the expected frequency of reference frequency signal is 32768 Hz, the frequency offset Δppm is 19.5, and the frequency of target frequency signal fₜ is 1 Hz, the frequency offset, Δppm, may occupy 0 cycles of the expected frequency, with a residue part of 10. Thus, the integral calibration value is equal to 0, and the fractional calibration value is equal to 10. In above examples, the integral calibration value and the fractional calibration value of the frequency offset may be determined according to a 30.5-scale system.

When the frequency division ratio is one half the ratio between the expected frequency of the reference frequency signal and the frequency of the target frequency signal, the integral calibration value may be determined according to the number of cycles of the expected frequency within ½fₜ of the frequency offset, and fractional calibration value may be determined according to the residue after determining the integral cycles of the expected frequency within ½fₜ of the frequency offset.

In some implementations, when the expected frequency of reference frequency signal is 32768 Hz, the ppm value of one cycle of the expected frequency is 30.5. If the frequency offset Δppm is equal to 100, and the frequency of target frequency signal fₜ is equal to 1 Hz, ½ of the frequency offset Δppm may occupy one cycle of the expected frequency, with a residue part of 19.5. Thus, the integral calibration value is equal to 1, and the fractional calibration value is equal to 19.5. In the above implementations, if the frequency of target frequency signal fₜ is 2 Hz, then ¼ of frequency offset may occupy 0 cycle of expected frequency with a residue of 20. In other words, the integer calibration value is equal to 0, and the fractional calibration value is equal to 20.

In accordance with yet another embodiment of the present disclosure, one cycle of the expected frequency may indicate the minimum cycle of the expected frequency.

At step 140, a calibrated frequency division ratio may be provided by calibrating the frequency division ratio according to the calibration value.

In some implementations, when the frequency offset has a positive value, i.e. the expected frequency is larger than the actual frequency. The integral part of the calibrated frequency division ratio may be determined by subtracting the integral calibration value from the frequency division ratio. When the frequency offset is a negative value, i.e. the expected frequency is smaller than the actual frequency, the integral part of the calibrated frequency division ratio may be determined by adding the integral calibration value to the frequency division ratio. The fractional calibration value may be provided as the residual part of the calibrated frequency division ratio.

It should be noted that the definition of a positive value and a negative value is interchangeable, as those skilled in the relevant art will recognize. For example, the frequency offset may be defined as a negative value when the expected frequency is larger than the actual frequency. In some implementations, positive or negative sign may be added to the frequency offset, the integral calibration value and the fractional calibration value, as those skilled in the relevant art will easily recognize.

Step 150, the target frequency signal may be provided by dividing the frequency of the reference frequency signal according to the calibrated frequency division ratio.

In some implementations, when the frequency division ratio is the ratio between the expected frequency of the reference frequency signal and the frequency of the target frequency signal, a counting value may be provided by counting the cycles of reference frequency signal; and a cycle of the target frequency signal may be started when the counting value starts from an initial value. The cycle of the target frequency signal may be ended when the counting value reaches to the integer part of the calibrated frequency division ratio and the cycles of the reference frequency signal may be re-counted from the initial value, in order to generate the next cycle of the target frequency signal. When one cycle of the target frequency signal is generated, the fractional calibration value may be added to the residual part of the calibrated frequency division ratio, and, after accumulated residues reaches an integer value, a post-carry integral part of the calibrated frequency division ratio may be provided by adding a carry from the integer value to the integral part of the calibrated frequency division ratio, and the fractional calibration value may be continuously added to the new residual part of the calibrated frequency division ratio. After one cycle of the target frequency signal is generated according to the post-carry integral part of the calibrated frequency division ratio, the post-carry integral part of the calibrated frequency division ratio may be reset to the initial integral value.

For example, the frequency of an expected frequency signal is 32768, the initial counting value is 0, the frequency of the target frequency signal is 1 Hz, and the integral part of the calibrated frequency division ratio is 32770 with a residue part of 10. One cycle of the target frequency signal may be started from the moment when the counting value is equal to 0 and the cycles of the actual frequency signal are counted. When the counting value reaches to the integral part of the calibrated frequency division ratio 32770, the cycle of the target frequency signal may be then ended and the counting value may be reset to 0 to start the next cycle of the target frequency signal. If one cycle of the target frequency signal is generated, the fractional calibration value may be added to the residue of the calibrated frequency division ratio. In other words, the residue part of the calibrated frequency division ratio may become 20. Then, after another cycle of the target frequency signal, the residue part becomes 30 after accumulation. After another cycle of the target frequency signal, the residue part becomes 40. Since the accumulated residues, 40, has reached to an integer value, 30.5, a carry is added to the calibrated frequency division to obtain a post-carry integer 32771, and the integer value, 30.5, is then subtracted from the accumulated residues to obtain a new residue of 9.5. After one more cycle of the target frequency signal is generated, the new residual part of the calibrated frequency value then increases from 9.5 to 19.5. After one cycle of the target frequency signal is generated according to the post-carry integer 32771 of the calibrated frequency division ratio, the post-carry integer 32771 may be reset to the initial value, 32770.

In accordance with yet another embodiment of the present disclosure, two methods may be provided to generate one cycle of the target frequency signal. The first method may include: inverting the target frequency signal when the counting value reaches a half of the calibrated frequency division ratio; resetting the counting value to the initial value; recounting the cycles of the reference frequency signal with the counting value starting from the initial value; inverting the target frequency signal when the counting value reaches one half of the calibrated frequency division ratio; generating one cycle of the target frequency signal, and resetting the counting value to the initial value to re-count the cycles of the reference frequency signal.

The second method may include: inverting the target frequency signal when the counting value reaches one half of the calibrated frequency division ratio; repeatedly updating the counting value; inverting the target frequency signal when the counting value reaches the frequency division ratio, providing one cycle of the target frequency signal; and resetting the counting value to the initial value to re-count the cycles of the reference frequency signal.

In some implementations, when the frequency division ratio is one half of the ratio between the expected frequency of the reference frequency signal and the frequency of the target frequency signal, a counting value may be provided by counting the cycles of the reference frequency signal. A half cycle of the target frequency signal may be started when the counting value starts from the initial value, and may be ended when the counting value reaches to the integer part of the calibrated frequency division ratio. Then, the cycles of the reference frequency signal may be re-counted from the initial value, in order to generate the next half cycle of the target frequency signal. When each half cycle of the target frequency signal is generated, the fractional calibration value may be added to the residual part of the calibrated frequency division ratio. When accumulated residues reach to an integer value, a post-carry integral part of the calibrated frequency division ratio may be provided by adding a carry from the integer value to the integral part of the calibrated frequency division ratio, and the fractional calibration value may be continuously added to the new residual part of the calibrated frequency division ratio. After one half cycle of the target frequency signal is produced according to the post-carry integral part of calibrated frequency division ratio, the post-carry integer may be reset to the initial integral value.

In some implementations, for example, assuming the frequency of the expected frequency signal is 32768, the counting value has an initial value of 0, the frequency of the target frequency signal is 1 Hz, and the integral part of the calibrated frequency division ratio is 16390, with a residual part of 10, one half cycle of the target frequency signal may be started when the counting value is 0. The cycles of the actual frequency signal may be counted. When the counting value reaches to the integral part of the calibrated frequency division ratio, 16390, the cycle of the target frequency signal may be ended, and the counting value may be reset to 0 in order to start the next half cycle of the target frequency signal. If one half cycle of the target frequency signal is generated, the fractional calibration value may be added to the residual part of the calibrated frequency division ratio. In other words, the residual part of the calibrated frequency division ratio becomes 20. After another half cycle of the target frequency signal, the accumulated residue becomes 30. Then, the accumulated residue becomes 40 another half cycle of the target frequency signal. Since the accumulated residue is larger than 30.5, a carry may be added to the calibrated frequency division to obtain a post-carry integral part, 16391, and 30.5 may be then subtracted from the accumulated residue to obtain a new residual part of 9.5. After another half cycle of the target frequency signal is generated, the accumulated residual part may increase from 9.5 to 19.5 by adding 10. After another half cycle of the target frequency signal is generated according to the post-carry integer, 16391, of the calibrated frequency division ratio, the post-carry integral part 16391 may be reset to 16390.

According to yet another embodiment of the present disclosure, a method may be provided to adjust the frequency division ratio according to the frequency offset of a reference frequency signal. The method may be applied to divide the frequency of any reference frequency signal into a required target frequency signal.

According to yet another embodiment of the present disclosure, an apparatus for calibrating frequency may be provided to adjust the frequency division ratio according to the frequency offset of a reference frequency signal. The apparatus may be applied in dividing the frequency of any reference frequency signal into a required target frequency signal.

FIG. 3 illustrates a flow diagram for calibrating frequency according to yet another embodiment of the present disclosure. An apparatus 300 for calibrating temperature-related frequency may include a module 310 for providing temperature, a module 320 for generating frequency signal, a module 330 for generating frequency offset, and a module 340 for calibrating frequency.

The Module 310 for providing temperature may be configured to acquire temperature of a crystal oscillator. For example, room temperature may be provided by a temperature sensor. An analog temperature may be converted into a digital temperature through an analog/digital converter or apparatus, as those skilled in the relevant art will recognize.

The Module 320 for generating frequency signal may be configured to acquire an actual frequency of the crystal oscillator.

The Module 330 for generating frequency offset may be configured to obtain the frequency offset between the actual frequency of the reference frequency signal and the expected frequency according to the temperature of the crystal oscillator.

In some implementations, the reference frequency signal may be generated by a crystal oscillator. Since the output frequency of the crystal oscillator is a function of temperature of the crystal oscillator, the actual frequency of a reference frequency signal generated by the crystal oscillator and the expected frequency may have a frequency offset. For example, if the expected frequency or an ideal frequency of the reference frequency signal generated by the crystal oscillator is 32768 Hz, the actual frequency may be only 32780 Hz or 32800 Hz with a frequency offset.

The frequency offset, defined as Δppm, may be a function of the temperature of a crystal oscillator. In general, each manufactured crystal oscillator may have an output frequency depending on the temperature of its internal material, as illustrated in FIG. 2. As shown in FIG. 2, a different temperature may correspond to a different output frequency from the crystal oscillator. The difference between an actual frequency and an expected frequency may be indicated as Δppm. For example, at the temperature, T₀, the actual frequency f₀ is 32.780 kHz, which is different from the expected frequency 32.768 kHz. The offset Δppm is (32768-32780)/32768*10⁶=244.1 ppm.

In some implementations, a lookup table for frequency offsets related to temperature may be provided according to a temperature-frequency characteristic, as illustrated in FIG. 2. The corresponding frequency offset may be provided in accordance with a particular temperature. In some implementations, an algorithm for temperature-related frequency offsets may also be produced according to a temperature-frequency characteristic, in which a frequency offset may be provided in accordance with the corresponding temperature.

In some implementations, the temperature of a crystal oscillator may be sensed by a temperature sensor. A digital temperature may be provided by converting an analog temperature signal from analog to digital. Depending on the temperature-frequency characteristic of each specific crystal oscillator, an actual output frequency of a specific crystal oscillator may be provided. The frequency offset needed for calibration may be provided according to the actual frequency. In some implementations, a corresponding frequency offset may be provided directly according to the digital temperature provided.

The Module 340 for calibrating frequency may be configured to determine the frequency division ratio according to the target frequency signal and the expected frequency of reference frequency signal, determine the calibration value of the frequency division ratio according to a frequency offset, and provide the target frequency signal by dividing the frequency of the reference frequency signal according to the calibrated frequency division ratio.

In some implementations, a frequency division ratio may be the ratio between the expected frequency of the reference frequency signal and the frequency of the target frequency signal. If the expected frequency of the reference frequency signal is fₘ, and the frequency of the target frequency signal is fₜ, then the frequency division ratio may be indicated as fₘ/fₜ. For example, if the expected frequency f, is 32768 Hz, and the frequency of target frequency signal fₜ is 1 Hz, the frequency division ratio may be equal to 32768 or 2¹⁵. For another example, if the expected frequency fₘ is 32768 Hz, and the target frequency signal fₜ is 2 Hz, then the frequency division ratio is equal to 16384, or 2¹⁴.

In some implementations, the frequency division ratio may also be one half of the ratio between the expected frequency of the reference frequency signal and the frequency of the target frequency signal, which may be indicated as fₘ/2fₜ. For example, if the expected frequency fₘ is 32768 Hz, and the target frequency signal fₜ is 1 Hz, then the frequency division ratio is equal to 16384, or 2¹⁴. For another example, if the expected frequency fₘ is equal to 32768 Hz, and the target frequency signal fₜ is 2 Hz, then the frequency division ratio is equal to 8192 or 2¹³.

The frequency division ratio may be provided according to the expected frequency. In general, there may be a frequency offset between the actual frequency of reference frequency and the expected frequency. A calibration value for the frequency division ratio may be provided according to the frequency offset. The calibration value may include an integral calibration value and a fractional calibration value.

In accordance with yet another embodiment of the present disclosure, two methods for providing calibration value may be provided with respect to two different ways for providing a frequency division ratio.

When a frequency division ratio is the ratio between the expected frequency of the reference frequency signal and the frequency of the target frequency signal, the integral calibration value may be determined according to the number of cycles of the expected frequency within 1/fₜ of the frequency offset, and fractional calibration value may be determined according to the residue after determining the integral cycles of the expected frequency within 1/fₜ of the frequency offset. In other words, the integral calibration value may be defined as the integral part of the ratio between the frequency offset, Δppm, to the ppm value of the cycles of expected frequency, and the fraction calibration may be defined as the residual part of the ratio between the frequency offset, Δppm, to the ppm value of the cycles of expected frequency.

In some implementations, when the expected frequency of the reference frequency signal is 32768 Hz, the ppm value of one cycle of expected frequency is equal to (1/32768*10⁶)=30.5. Thus, when the frequency offset Δppm is 100 ppm, and the frequency of target frequency signal fₜ is 1 Hz, the frequency offset, Δppm, may occupy 3 cycles of the expected frequency, with a residue part of 8.5. In other words, the integral calibration value is equal to 3, and the fractional calibration value is equal to 8.5. For another example, if the frequency of target frequency signal fₜ is equal to 2 Hz, then one half of the frequency offset Δppm equals 50 ppm, which occupies one cycle of the expected frequency, with a residue part of 19.5. In other words, the integral calibration value is equal to 1, and the fractional calibration value is equal to 19.5. In some other implementations, when the expected frequency of reference frequency signal is 32768 Hz, the frequency offset Δppm is 19.5, and the frequency of target frequency signal fₜ is 1 Hz, the frequency offset, Δppm, may occupy 0 cycles of the expected frequency, with a residue part of 10. Thus, the integral calibration value is equal to 0, and the fractional calibration value is equal to 10. In the above examples, the integral calibration value and the fractional calibration value of the frequency offset may be determined according to a 30.5-scale system.

When the frequency division ratio is one half the ratio between the expected frequency of the reference frequency signal and the frequency of the target frequency signal, the integral calibration value may be determined according to the number of cycles of the expected frequency within ½fₜ of the frequency offset, and fractional calibration value may be determined according to the residue after determining the integral cycles of the expected frequency within ½fₜ of the frequency offset.

In some implementations, when the expected frequency of reference frequency signal is 32768 Hz, the ppm value of one cycle of the expected frequency is 30.5. If the frequency offset, Δppm, is equal to 100, and the frequency of target frequency signal fₜ is equal to 1 Hz, ½ of the frequency offset, Δppm, may occupy one cycle of the expected frequency, with a residue part of 19.5. Thus, the integral calibration value is equal to 1, and the fractional calibration value is equal to 19.5. In the above implementations, if the frequency of target frequency signal fₜ is 2 Hz, then ¼ of frequency offset may occupy 0 cycle of expected frequency with a residue of 20. In other words, the integer calibration value is equal to 0, and the fractional calibration value is equal to 20.

In accordance with yet another embodiment of the present disclosure, one cycle of the expected frequency may indicate the minimum cycle of the expected frequency.

The calibrated frequency division ratio may be provided by calibrating the frequency division ratio according to the calibration value. In some implementations, when the frequency offset has a positive value, i.e., the expected frequency is larger than the actual frequency, the integral part of the calibrated frequency division ratio may be determined by subtracting the integral calibration value from the frequency division ratio. When the frequency offset is a negative value, i.e., the expected frequency is smaller than the actual frequency, the integral part of the calibrated frequency division ratio may be determined by adding the integral calibration value to the frequency division ratio. The fractional calibration value may be provided as the residual part of the calibrated frequency division ratio.

It should be noted that the definition of a positive value and a negative value is interchangeable, as those skilled in the relevant art will recognize. For example, the frequency offset may be defined as a negative value when the expected frequency is larger than the actual frequency. In some implementations, positive or negative sign may be added to the frequency offset, the integral calibration value and the fractional calibration value, as those skilled in the relevant art will easily recognize.

The target frequency signal may be provided by dividing the frequency of the reference frequency signal according to the calibrated frequency division ratio. In some implementations, when the frequency division ratio is the ratio between the expected frequency of the reference frequency signal and the frequency of the target frequency signal, a counting value may be provided by counting the cycles of reference frequency signal; and a cycle of the target frequency signal may be started when the counting value starts from an initial value. The cycle of the target frequency signal may be ended when the counting value reaches to the integer part of the calibrated frequency division ratio and the cycles of the reference frequency signal may be re-counted from the initial value, in order to generate the next cycle of the target frequency signal. When one cycle of the target frequency signal is generated, the fractional calibration value may be added to the residual part of the calibrated frequency division ratio, and, after accumulated residues reaches an integer value, a post-carry integral part of the calibrated frequency division ratio may be provided by adding a carry from the integer value to the integral part of the calibrated frequency division ratio, and the fractional calibration value may be continuously added to the new residual part of the calibrated frequency division ratio. After one cycle of the target frequency signal is generated according to the post-carry integral part of the calibrated frequency division ratio, the post-carry integral part of the calibrated frequency division ratio may be reset to the initial integral value.

For example, the frequency of an expected frequency signal is 32768, the initial counting value is 0, the frequency of the target frequency signal is 1 Hz, and the integral part of the calibrated frequency division ratio is 32770 with a residue part of 10. One cycle of the target frequency signal may be started from the moment when the counting value is equal to 0 and the cycles of the actual frequency signal are counted. When the counting value reaches to the integral part of the calibrated frequency division ratio 32770, the cycle of the target frequency signal may be then ended and the counting value may be reset to 0 to start the next cycle of the target frequency signal. If one cycle of the target frequency signal is generated, the fractional calibration value may be added to the residue of the calibrated frequency division ratio. In other words, the residue part of the calibrated frequency division ratio may become 20. Then, after another cycle of the target frequency signal, the residue part becomes 30 after accumulation. After another cycle of the target frequency signal, the residue part becomes 40. Since the accumulated residues, 40, has reached to an integer value, 30.5, a carry is added to the calibrated frequency division to obtain a post-carry integer 32771, and the integer value, 30.5, is then subtracted from the accumulated residues to obtain a new residue of 9.5. After one more cycle of the target frequency signal is generated, the new residual part of the calibrated frequency value then increases from to 19.5. After one cycle of the target frequency signal is generated according to the post-carry integer 32771 of the calibrated frequency division ratio, the post-carry integer 32771 may be reset to the initial value, 32770.

In accordance with yet another embodiment of the present disclosure, two methods may be provided to generate one cycle of the target frequency signal. The first method may include: inverting the target frequency signal when the counting value reaches one half of the calibrated frequency division ratio; resetting the counting value to the initial value; recounting the cycles of the reference frequency signal with the counting value starting from the initial value; inverting the target frequency signal when the counting value reaches one half of the calibrated frequency division ratio; generating one cycle of the target frequency signal; and resetting the counting value to the initial value to re-count the cycles of the reference frequency signal.

The second method may include: inverting the target frequency signal when the counting value reaches one half of the calibrated frequency division ratio; continuing to update the counting value; inverting the target frequency signal when the counting value reaches the frequency division ratio, providing one cycle of the target frequency signal; and resetting the counting value to the initial value to re-count the cycles of the reference frequency signal.

In some implementations, when the frequency division ratio is one half of the ratio between the expected frequency of the reference frequency signal and the frequency of the target frequency signal, a counting value may be provided by counting the cycles of the reference frequency signal. A half cycle of the target frequency signal may be started when the counting value starts from the initial value, and may be ended when the counting value reaches the integer part of the calibrated frequency division ratio. Then the cycles of the reference frequency signal may be re-counted from the initial value in order to generate the next half cycle of the target frequency signal. When each half cycle of the target frequency signal is generated, the fractional calibration value may be added to the residual part of the calibrated frequency division ratio. When accumulated residues reach an integer, post-carry integer of calibrated frequency division ratio is provided by adding a carry to the integral part of the calibrated frequency division ratio, with fractional calibration value continually being accumulated thereafter on the basis of the new residue of calibrated frequency division ratio, and, after a half cycle of target frequency signal is produced on the basis of post-carry integer of calibrated frequency division ratio, the post-carry integer is reset to the initial integer.

In some implementations, for example, assuming the frequency of the expected frequency signal is 32768, the counting value has an initial value of 0, the frequency of the target frequency signal is 1 Hz, and the integral part of the calibrated frequency division ratio is 16390, with a residual part of 10, one half cycle of the target frequency signal may be started when the counting value is 0. The cycles of the actual frequency signal may be counted. When the counting value reaches to the integral part of the calibrated frequency division ratio, 16390, the cycle of the target frequency signal may be ended, and the counting value may be reset to 0 in order to start the next half cycle of the target frequency signal. If one half cycle of the target frequency signal is generated, the fractional calibration value may be added to the residual part of the calibrated frequency division ratio. In other words, the residual part of the calibrated frequency division ratio becomes 20. After another half cycle of the target frequency signal, the accumulated residue becomes 30. Then, the accumulated residue becomes 40 after another half cycle of the target frequency signal. Since the accumulated residue is larger than 30.5, a carry may be added to the calibrated frequency division to obtain a post-carry integral part, 16391, and 30.5 may then be subtracted from the accumulated residue to obtain a new residual part of 9.5. After another half cycle of the target frequency signal is generated, the accumulated residual part may increase from 9.5 to 19.5 by adding 10. After another half cycle of the target frequency signal is generated according to the post-carry integer, 16391, of the calibrated frequency division ratio, the post-carry integral part 16391 may be reset to 16390.

According to yet another embodiment of the present disclosure, a method may be provided to adjust the frequency division ratio according to the frequency offset of a reference frequency signal. The method may be applied to divide the frequency of any reference frequency signal into a required target frequency signal.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” As used herein, the terms “connected,” “coupled,” or any variant thereof, means any connection or coupling, either direct or indirect, between two or more elements; the coupling of connection between the elements can be physical, logical, or a combination thereof. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or,” in reference to a list of two or more items, covers all the following interpretations of the word: any of the items in the list, all of the items in the list, and any combination of the items in the list.

The above detailed description of embodiments of the disclosure is not intended to be exhaustive or to limit the teachings to the precise form disclosed above. While specific embodiments of, and examples for the disclosure, are described above for illustrative purposes, various equivalent modifications are possible within the scope of the disclosure, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed in parallel, or may be performed at different times. Further any specific numbers noted herein are only examples; alternative implementations may employ differing values or ranges.

The teaching of the disclosure provided herein can be applied to other systems, not necessarily the system described above. The elements and acts of the various embodiments described above can be combined to provide further embodiments.

Any patents and applications and other references noted above, including any that may be listed in accompanying filing papers, are incorporated herein by reference. Aspects of the disclosure can be modified, if necessary, to employ the systems, functions, and concepts of the various references described above to provide yet further embodiments of the disclosure.

These and other changes can be made to the disclosure in light of the above Detailed Description. While the above description describes certain embodiments of the disclosure, and describes the best mode contemplated, no matter how detailed the above appears in text, the teachings can be practiced in many ways. Details of the system may vary considerably in its implementation details, while still being encompassed by the subject matter disclosed herein. As noted above, particular terminology used when describing certain features or aspects of the disclosure should not be taken to imply that the terminology is being redefined herein to be restricted to any specific characteristics, features, or aspects of the disclosure with which that terminology is associated. In general, the terms used in the following claims should not be construed to limit the disclosure to the specific embodiments disclosed in the specification, unless the above Detailed Description section explicitly defines such terms. Accordingly, the actual scope of the disclosure encompasses not only the disclosed embodiments, but also all equivalent ways of practicing or implementing the disclosure under the claims.

What is claimed is:

1. A method of calibrating frequency, the method comprising:
providing an actual frequency of a reference frequency signal and a frequency offset between the actual frequency of the reference frequency signal and an expected frequency of the reference frequency signal;
determining a frequency division ratio according to the frequency of a target frequency signal and the expected frequency of the reference frequency signal;
determining a calibration value of the frequency division ratio according to the frequency offset;
providing a calibrated frequency division ratio by calibrating the frequency division ratio according to the calibration value; and
providing the target frequency signal by dividing the frequency of the reference frequency signal according to the calibrated frequency division ratio.

2. A method as recited in claim 1, wherein the frequency division ratio is the ratio between the expected frequency of the reference frequency signal and the frequency of the target frequency signal;
wherein the calibration value includes an integral calibration value and a fractional calibration value;
wherein the step for providing the calibrated frequency division ratio by calibrating the frequency division ratio according to the calibration value comprises the steps of: providing the integral part of the calibrated frequency division ratio by adding or subtracting the frequency division ratio from the integral calibration value; and taking the fractional calibration value as the residual part of the calibrated frequency division ratio.

3. A method as recited in claim 2, wherein providing the target frequency signal by dividing the frequency of the reference frequency signal according to the calibrated frequency division ratio comprises:
providing a counting value by counting the cycles of the reference frequency signal; and
starting one cycle of the target frequency signal when the counting value starts from an initial value, and ending the cycle of the target frequency signal when the counting value reaches to the integral part of the calibrated frequency division ratio, and re-counting the cycles of the reference frequency signal from the initial value to generate the next cycle of the target frequency signal;
wherein, when one cycle of the target frequency signal is generated, the fractional calibration value is added to the residual part of the calibrated frequency division ratio, and, after accumulated residues reaches an integer value, a post-carry integral part of the calibrated frequency division ratio is provided by adding a carry from the integer value to the integral part of the calibrated frequency division ratio, and the fractional calibration value is continuously added to the new residual part of the calibrated frequency division ratio; after one cycle of the target frequency signal is generated according to the post-carry integral part of the calibrated frequency division ratio, the post-carry integral part of the calibrated frequency division ratio is reset to the initial integral value.

4. A method as recited in claim 2, wherein the integral calibration value and the fractional calibration value is determined according to, respectively, the number of cycles and the residue cycles of the expected frequency within 1/fₜ of the frequency offset; wherein fₜ is the frequency of the target frequency signal.

5. A method as recited in claim 1, wherein the frequency division ratio is equal to one half of the ratio between the expected frequency of the reference frequency signal and the frequency of the target frequency signal, and the calibration value includes an integral calibration value and a fractional calibration value;
wherein the step of providing calibrated frequency division ratio by calibrating frequency division ratio according to the calibration value comprises the steps of: providing the integral part of the calibrated frequency division ratio by adding or subtracting the integral calibration value to or from the frequency division ratio; and providing the fractional calibration value as the residual part of the calibrated frequency division ratio.

6. A method as recited in claim 5, wherein providing the target frequency signal by dividing the frequency of the reference frequency signal according to the calibrated frequency division ratio comprises:
providing a counting value by counting the cycles of the reference frequency signal; and
inverting the target frequency signal when the count value reaches the calibrated frequency division ratio, and recounting the cycles of the reference frequency signal by starting from an initial value of the counting value;
wherein, after a half cycle of the target frequency signal is generated, the fractional calibration value is added to the residual part of the calibrated frequency division ratio, and, after accumulated residues reach an integer value, a post-carry integer of the calibrated frequency division ratio is provided by adding a carry from the integer value to the integral part of the calibrated frequency division ratio, and the fractional calibration value is continuously added to the new residual part of the calibrated frequency division ratio;
wherein, after one half cycle of target frequency signal is generated according to the post-carry integral part of the calibrated frequency division ratio, the post-carry integral part of the calibrated frequency division ratio is reset to the initial integral value.

7. A method as recited in claim 5, wherein the integral calibration value and the fractional calibration value are determined according to, respectively, the number of double cycles and the residue of double cycles of the expected frequency within ½fₜ of the frequency offset; wherein fₜ is the frequency of the target frequency signal.

8. An apparatus for calibrating frequency, comprising:
a first module, configured to acquire a temperature of a crystal oscillator and provide the temperature;
a second module, configured to provide the actual frequency of a reference frequency signal from the crystal oscillator;
a third module, configured to provide a frequency offset between the actual frequency of the reference frequency signal and the expected frequency of the reference frequency signal according to the temperature; and
a fourth module, configured to determine a frequency division ratio according to the frequency of the target frequency signal and the expected frequency of the reference frequency signal, determine a calibration value of the frequency division ratio according to the frequency offset, provide the calibrated frequency division ratio by calibrating the frequency division ratio according to the calibration value, and determine the target frequency signal by dividing the frequency of the reference frequency signal according to the calibrated frequency division ratio.

9. An apparatus as recited in claim 8, wherein the frequency division ratio is the ratio between the expected frequency of the reference frequency signal and the frequency of the target frequency signal and the calibration value comprises an integral calibration value and a fractional calibration value;
wherein providing the calibrated frequency division ratio by calibrating the frequency division ratio according to the calibration value comprises: providing the integral part of the calibrated frequency division ratio by adding or subtracting the integral calibration value to or from the frequency division ratio; and providing the fractional calibration value as the residual part of the calibrated frequency division ratio.

10. An apparatus as recited in claim 9, wherein the step of determining the target frequency signal by dividing the frequency of the reference frequency signal according to the calibrated frequency division ratio comprises:
providing a counting value by counting the cycles of the reference frequency signal;
starting one cycle of the target frequency signal when the counting value starts from an initial value, and ending the cycle of the target frequency signal when the counting value reaches the integral part of the calibrated frequency division ratio; and
re-counting the cycles of the reference frequency signal from the initial value to generate the next cycle of the target frequency signal;
wherein, when a cycle of the target frequency signal is generated, the fractional calibration value is added to the residual part of the calibrated frequency division ratio, and, after accumulated residues reaches an integer value, a post-carry integral part of the calibrated frequency division ratio is provided by adding a carry from the integer value to the integral part of the calibrated frequency division ratio, and the fractional calibration value is continuously added to the new residual part of the calibrated frequency division ratio;
wherein, after one cycle of the target frequency signal is obtained according to the post-carry integral part of the calibrated frequency division ratio, the post-carry integral part of the calibrated frequency division ratio is reset to the initial integral part of the calibrated frequency division ratio.

11. An apparatus as recited in claim 9, wherein the integral calibration value and the fractional calibration value are determined according to, respectively, the number of cycles and the residue cycles of the expected frequency within 1/fₜ of the frequency offset; wherein fₜ is the frequency of the target frequency signal.

12. An apparatus as recited in claim 8, wherein the frequency division ratio is equal to one half of the ratio between the expected frequency of the reference frequency signal and the frequency of the target frequency signal, and the calibration value includes an integral calibration value and a fractional calibration value;
wherein providing calibrated frequency division ratio by calibrating frequency division ratio according to the calibration value comprises: providing the integral part of the calibrated frequency division ratio by adding or subtracting the integral calibration value to or from the frequency division ratio; and providing the fractional calibration value as the residual part of the calibrated frequency division ratio.

13. An apparatus as recited in claim 12, wherein providing the target frequency signal by dividing the frequency of the reference frequency signal according to the calibrated frequency division ratio comprises:
providing a counting value by counting the cycles of the reference frequency signal; and
inverting the target frequency signal when the count value reaches the calibrated frequency division ratio, and recounting the cycles of the reference frequency signal by starting from an initial value of the counting value;
wherein, after a half cycle of the target frequency signal is generated, the fractional calibration value is added to the residual part of the calibrated frequency division ratio, and, after accumulated residues reach an integer value, a post-carry integer of the calibrated frequency division ratio is provided by adding a carry from the integer value to the integral part of the calibrated frequency division ratio, and the fractional calibration value is continuously added to the new residual part of the calibrated frequency division ratio;
wherein, after one half cycle of target frequency signal is generated according to the post-carry integral part of the calibrated frequency division ratio, the post-carry integral part of the calibrated frequency division ratio is reset to the initial integral value.

14. An apparatus as recited in claim 12, wherein the integral calibration value and the fractional calibration value are determined according to, respectively, the number of double cycles and the residue of double cycles of the expected frequency within ½fₜ of the frequency offset; wherein fₜ is the frequency of the target frequency signal.
